(19) United States
(12) Patent Application Publication
(10) Pub. No.: US 2026/0363092 A1
(43) Pub. Date: Nov. 12, 2026

(54) SEMICONDUCTOR DEVICE, SEMICONDUCTOR PACKAGE, AND METHOD OF MANUFACTURING SEMICONDUCTOR DEVICE

(71) Applicant: ROHM CO., LTD., Kyoto (JP)

(72) Inventors: Kosuke YAMASHIRO, Kyoto-shi (JP); Toru HIGUCHI, Kyoto-shi (JP); Tetsuo TATEISHI, Kyoto-shi (JP)

(73) Assignee: ROHM CO., LTD., Kyoto (JP)

(21) Appl. No.: 19/706,545

(22) Filed: Jun. 12, 2026

Related U.S. Application Data
(63) Continuation of application No. PCT/JP2024/044890, filed on Dec. 19, 2024.

(30) Foreign Application Priority Data
Dec. 20, 2023 (JP) 2023-214392
Dec. 18, 2024 (JP) 2024-221679

(51) Int. Cl. H10W 46/00; H10D 30/01; H10W 20/40; H10W 20/41

(52) U.S. Cl. CPC H10W 46/103; H10D 30/027; H10W 20/435; H10W 20/482; H10W 46/106

(57) ABSTRACT

A semiconductor device includes a semiconductor substrate. A modified portion is formed inside the semiconductor substrate. The modified portion indicates information regarding manufacturing steps of the semiconductor device.

### TECHNICAL FIELD

The present disclosure relates to a semiconductor device, a semiconductor package, and a method of manufacturing a semiconductor device.

### BACKGROUND ART

Japanese Patent No. 7355970 (PTL 1), for example, describes a semiconductor device. The semiconductor device described in PTL 1 has a semiconductor substrate. In the semiconductor device described in PTL 1, for example, marking is performed on a main surface of the semiconductor substrate. The marking is formed by irradiating the main surface of the semiconductor substrate with a laser beam.

### CITATION LIST

### Patent Literature

PTL 1: Japanese Patent No. 7355970

### BRIEF DESCRIPTION OF DRAWINGS

FIG. 1 is a plan view of a semiconductor device 100.

FIG. 2 is a plan view of semiconductor devices 100 before singulation.

FIG. 3 is a cross-sectional view along III-III in FIG. 1.

FIG. 4 is an enlarged plan view showing a first example of a manner of formation of a modified portion 14.

FIG. 5 is an enlarged plan view showing a second example of the manner of formation of modified portion 14.

FIG. 6 is an enlarged plan view showing a third example of the manner of formation of modified portion 14.

FIG. 7 is an enlarged plan view showing a fourth example of the manner of formation of modified portion 14.

FIG. 8A is a cross-sectional view of a semiconductor package 200.

FIG. 8B is a plan view of semiconductor package 200.

FIG. 9 is a diagram of manufacturing steps of semiconductor device 100.

FIG. 10 is a cross-sectional view illustrating an element isolation film formation step S2.

FIG. 11 is a cross-sectional view illustrating a first ion implantation step S3.

FIG. 12 is a cross-sectional view illustrating a gate insulating film formation step S4.

FIG. 13 is a cross-sectional view illustrating a gate electrode formation step S5.

FIG. 14 is a cross-sectional view illustrating a second ion implantation step S6.

FIG. 15 is a cross-sectional view illustrating a sidewall spacer formation step S7.

FIG. 16 is a cross-sectional view illustrating a third ion implantation step S8.

FIG. 17 is a cross-sectional view illustrating a first interlayer insulating film formation step S9.

FIG. 18 is a cross-sectional view illustrating a contact plug formation step S10.

FIG. 19 is a cross-sectional view illustrating a first interconnect formation step S11.

FIG. 20 is a cross-sectional view illustrating a second interlayer insulating film formation step S12.

FIG. 21 is a cross-sectional view illustrating a via plug formation step S13.

FIG. 22 is a cross-sectional view illustrating a second interconnect formation step S14.

FIG. 23 is a cross-sectional view illustrating a protective film formation step S15.

FIG. 24 is a cross-sectional view showing a first example of a marking step S17.

FIG. 25 is a cross-sectional view showing a second example of marking step S17.

FIG. 26 is an enlarged plan view showing a first example of a manner of formation of modified portion 14 in a semiconductor device 100A.

FIG. 27 is a schematic cross-sectional view along XXVII-XXVII in FIG. 26.

FIG. 28 is an enlarged plan view showing a second example of the manner of formation of modified portion 14 in semiconductor device 100A.

FIG. 29 is an enlarged plan view showing a third example of the manner of formation of modified portion 14 in semiconductor device 100A.

FIG. 30 is a schematic plan view along XXX-XXX in FIG. 29.

FIG. 31 is a plan view showing a first example of a semiconductor package 200A.

FIG. 32 is a schematic cross-sectional view along XXXII-XXXII in FIG. 31.

FIG. 33 is a plan view showing a second example of semiconductor package 200A.

FIG. 34 is a schematic cross-sectional view along XXXIV-XXXIV in FIG. 33.

FIG. 35 is a plan view showing a third example of semiconductor package 200A.

FIG. 36 is a schematic cross-sectional view along XXXVI-XXXVI in FIG. 35.

FIG. 37 is a cross-sectional view of a semiconductor device 100B.

### DESCRIPTION OF EMBODIMENTS

### Detailed Description

Semiconductor devices according to embodiments of the present disclosure will be described. In the drawings below, the same or corresponding portions are denoted by the same reference characters, and redundant description will not be repeated.

### First Embodiment

A semiconductor device according to a first embodiment will be described. The semiconductor device according to the first embodiment will be referred to as a semiconductor device 100.

### Configuration of Semiconductor Device 100

A configuration of semiconductor device 100 will be described below.

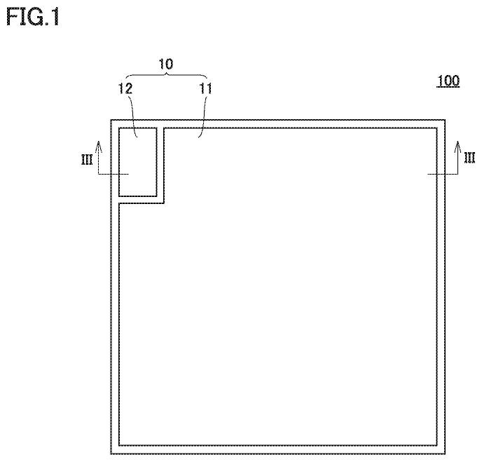

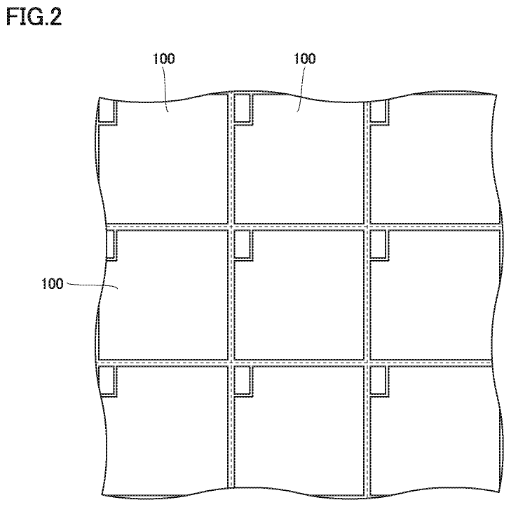

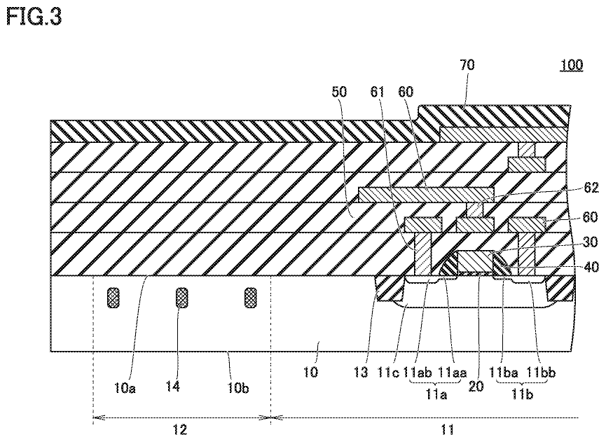

FIG. 1 is a plan view of semiconductor device 100. FIG. 2 is a plan view of semiconductor devices 100 before singulation. FIG. 3 is a cross-sectional view along III-III in FIG. 1. As shown in FIGS. 1 to 3, semiconductor device 100 includes a semiconductor substrate 10, a gate insulating film 20, a gate electrode 30, a sidewall spacer 40, an interlayer insulating film 50, an interconnect 60, a contact plug 61 and a via plug 62, and a protective film 70.

Semiconductor substrate 10 has a main surface 10a and a main surface 10b. Main surface 10b is opposite to main surface 10a. Main surface 10a and main surface 10b are end surfaces in a thickness direction of semiconductor substrate 10. A constituent material for semiconductor substrate 10 is, for example, monocrystalline silicon. The constituent material for semiconductor substrate 10 is not limited as such. The constituent material for semiconductor substrate 10 may be, for example, silicon carbide or gallium nitride.

Plan view herein refers to viewing along a normal direction of main surface 10a. Semiconductor substrate 10 has a device region 11 and a marking region 12 in plan view. Device region 11 is a region where circuit elements such as transistors are formed. Marking region 12 is a region where information regarding manufacturing steps of semiconductor device 100 is held. Device region 11 and marking region 12 are located inside an outer peripheral edge of semiconductor substrate 10 in plan view. More specifically, device region 11 and marking region 12 are located inside a scribe lane (not shown) of a semiconductor wafer. The semiconductor wafer is singulated into a plurality of semiconductor devices 100 by being cut along a boundary region between two adjacent semiconductor devices 100, where the boundary region is the scribe lane.

In device region 11, semiconductor substrate 10 has a source region 11a, a drain region 11b, and a well region 11c. Source region 11a is formed in main surface 10a. Drain region 11b is formed in main surface 10a so as to be spaced apart from source region 11a. Well region 11c is formed in main surface 10a so as to surround source region 11a and drain region 11b in cross-sectional view along the normal direction of main surface 10a.

A conductivity type of source region 11a and a conductivity type of drain region 11b are opposite to a conductivity type of well region 11c. For example, if the conductivity type of source region 11a and the conductivity type of drain region 11b is n type, the conductivity type of well region 11c is p type. A portion of well region 11c located between source region 11a and drain region 11b may be referred to as a channel region.

Source region 11a has a first region 11aa and a second region 11ab. Drain region 11b has a first region 11ba and a second region 11bb. First region 11aa is located closer to drain region 11b than second region 11ab, and first region 11ba is located closer to source region 11a than second region 11bb. A dopant concentration in first region 11aa is lower than a dopant concentration in second region 11ab, and a dopant concentration in first region 11ba is lower than a dopant concentration in second region 11bb. That is, source region 11a and drain region 11b have an LDD (Lightly Doped Diffusion) structure.

An element isolation film 13 is formed in main surface 10a. Element isolation film 13 surrounds well region 11c in plan view. A constituent material for element isolation film 13 is, for example, silicon oxide. Element isolation film 13 is embedded, for example, in a trench formed in main surface 10a. That is, element isolation film 13 is an STI (Shallow Trench Isolation). Element isolation film 13 may be a LOCOS (Local Oxidation Of Silicon).

Gate insulating film 20 is disposed on main surface 10a in device region 11. More specifically, gate insulating film 20 is disposed on the channel region. A constituent material for gate insulating film 20 is, for example, silicon oxide. Gate electrode 30 is disposed on gate insulating film 20. That is, gate electrode 30 is disposed to face the channel region with gate insulating film 20 interposed therebetween. A constituent material for gate electrode 30 is, for example, polycrystalline silicon containing a dopant. Source region 11a, drain region 11b, well region 11c, gate insulating film 20, and gate electrode 30 constitute a transistor, and two adjacent such transistors are isolated from each other by element isolation film 13.

Sidewall spacer 40 is disposed on main surface 10a in device region 11. More specifically, sidewall spacer 40 is disposed on first region 11aa and first region 11ba so as to be in contact with side surfaces of gate electrode 30. A constituent material for sidewall spacer 40 is, for example, silicon oxide.

Lowermost interlayer insulating film 50 is disposed on main surface 10a so as to cover element isolation film 13, gate electrode 30, and sidewall spacer 40. Interconnect 60 is disposed on interlayer insulating film 50. Lowermost interconnect 60 is electrically connected to source region 11a (first region 11aa) and drain region 11b (second region 11bb) by contact plug 61. Although not shown, lowermost interconnect 60 is also electrically connected to gate electrode 30 by contact plug 61. Contact plug 61 is embedded in a contact hole formed in lowermost interlayer insulating film 50.

Upper interlayer insulating film 50 is disposed on lower interlayer insulating film 50 so as to cover interconnect 60 disposed on lower interlayer insulating film 50. Vertically adjacent interconnects 60 are electrically connected to each other by via plug 62. Via plug 62 is embedded in a via hole formed in interlayer insulating film 50 other than the lowermost one. Protective film 70 is disposed on uppermost interlayer insulating film 50 so as to cover uppermost interconnect 60.

A constituent material for interlayer insulating film 50 is, for example, silicon oxide. A constituent material for interconnect 60 is, for example, aluminum or an aluminum alloy. A constituent material for contact plug 61 and a constituent material for via plug 62 are, for example, tungsten. A constituent material for protective film 70 is, for example, silicon nitride.

In marking region 12, a modified portion 14 is formed inside semiconductor substrate 10. Modified portion 14 is a portion of semiconductor substrate 10 into which a defect (such as a dislocation) is introduced. Modified portion 14 indicates information regarding manufacturing steps of semiconductor device 100. The information regarding the manufacturing steps of semiconductor device 100 is, for example, at least one of: a result of an inspection during the manufacturing of semiconductor device 100; a lot number of a semiconductor wafer from which semiconductor device 100 is obtained; and a position of semiconductor device 100 on the semiconductor wafer. However, the information regarding the manufacturing steps of semiconductor device 100 is not limited as such. A crack may or may not be introduced into modified portion 14. The information regarding the manufacturing steps of semiconductor device 100 may include, for example, a company code or a product code. In order to ensure traceability for each semiconductor device 100, the information regarding the manufacturing steps of semiconductor device 100 may vary for each semiconductor device 100. In order to ensure traceability of causes of defects in the manufacturing steps, the information regarding the manufacturing steps of semiconductor device 100 may include an ID that identifies a manufacturing apparatus used in the manufacturing steps of semiconductor device 100 or the like.

Interconnect 60 is disposed so as not to overlap marking region 12 in plan view. A portion of main surface 10a overlapping modified portion 14 in plan view has an arithmetic mean roughness (Ra) of 1 nm or less. Stated from a different perspective, the arithmetic mean roughness of the portion of main surface 10a overlapping modified portion 14 in plan view is approximately equal to the arithmetic mean roughness of a portion of main surface 10a not overlapping modified portion 14 in plan view.

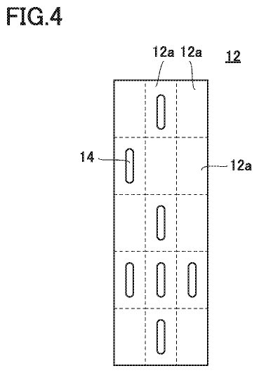

FIG. 4 is an enlarged plan view showing a first example of a manner of formation of modified portion 14. As shown in FIG. 4, marking region 12 may be partitioned into a plurality of regions 12a disposed in a matrix (indicated by dotted lines in FIG. 4). The information regarding the manufacturing steps of semiconductor device 100 is indicated by whether or not modified portion 14 is formed in each of the plurality of regions 12a. Marking region 12 may have a plurality of columns of regions 12a. One column of regions 12a and another column of regions 12a indicate mutually different pieces of information regarding the manufacturing steps of semiconductor device 100.

In the example of FIG. 4, a leftmost column (first column) of regions 12a indicates the lot number of the semiconductor wafer; a column (second column) of regions 12a located to the right of the first column indicates the position of semiconductor device 100 on the semiconductor wafer; and a column (third column) of regions 12a located to the right of the second column indicates the result of the inspection during the manufacturing of semiconductor device 100.

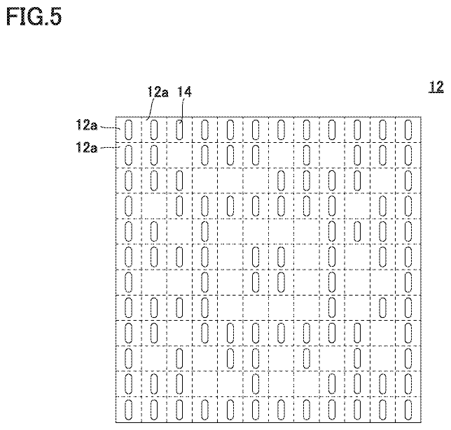

FIG. 5 is an enlarged plan view showing a second example of the manner of formation of modified portion 14. As shown in FIG. 5, in the second example as well, the information regarding the manufacturing steps of semiconductor device 100 is indicated by whether or not modified portion 14 is formed in each of the plurality of regions 12a, where modified portions 14 arranged two-dimensionally in plan view form a QR code (registered trademark).

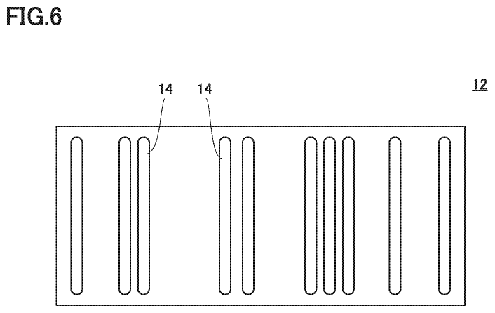

FIG. 6 is an enlarged plan view showing a third example of the manner of formation of modified portion 14. In the third example, as shown in FIG. 6, modified portions 14 extend along a first direction DR1 in plan view, and are arranged along a second direction DR2 in plan view. Second direction DR2 is a direction perpendicular to first direction DR1 in plan view. In the third example, the information regarding the manufacturing steps of semiconductor device 100 is indicated by a spacing between two adjacent modified portions 14 in second direction DR2. Stated from a different perspective, the arrangement of modified portions 14 may form a bar code.

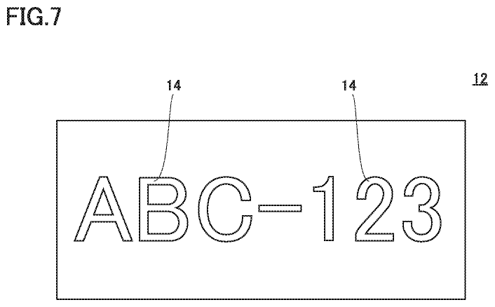

FIG. 7 is an enlarged plan view showing a fourth example of the manner of formation of modified portion 14. As shown in FIG. 7, modified portions 14 may be arranged so as to form characters and numbers. In the fourth example, the information regarding the manufacturing steps of semiconductor device 100 is indicated by the characters and numbers.

### Configuration of Semiconductor Package 200

A configuration of a semiconductor package using semiconductor device 100 will be described below. The semiconductor package using semiconductor device 100 will be referred to as a semiconductor package 200.

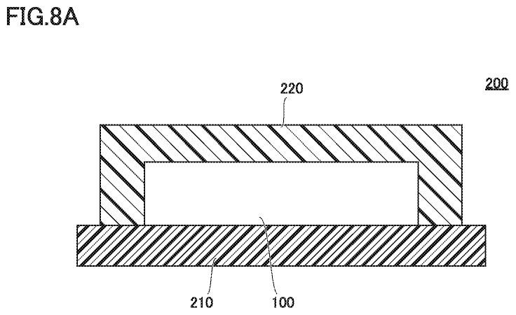

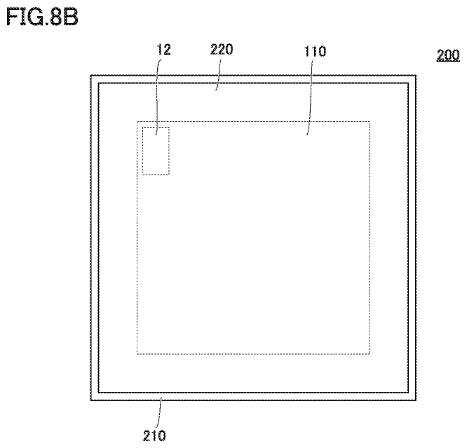

FIG. 8A is a cross-sectional view of semiconductor package 200. FIG. 8B is a plan view of semiconductor package 200. As shown in FIGS. 8A and 8B, semiconductor package 200 includes semiconductor device 100, a substrate 210, and a sealing member 220. Substrate 210 is, for example, a printed circuit board (PCB). Semiconductor device 100 is disposed on and electrically connected to substrate 210. Sealing member 220 seals semiconductor device 100 on substrate 210. More specifically, sealing member 220 is, for example, a mold resin, and is disposed on substrate 210 so as to cover semiconductor device 100. A portion of semiconductor package 200 overlapping marking region 12 in plan view, for example, a portion of sealing member 220 overlapping marking region 12 in plan view, is formed of a material that does not obstruct X-rays, infrared light, terahertz waves, visible light, or other electromagnetic waves used for reading a marking provided on marking region 12.

### Method of Manufacturing Semiconductor Device 100

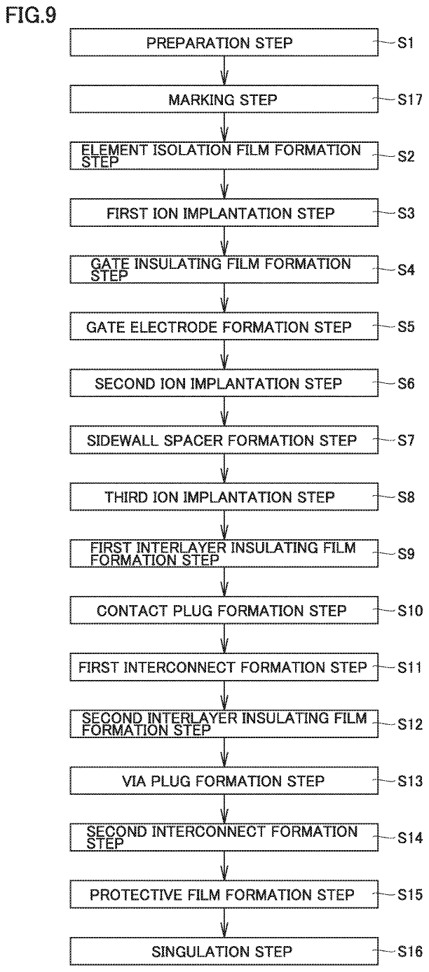

FIG. 9 is a diagram of manufacturing steps of semiconductor device 100. As shown in FIG. 9, a method of manufacturing semiconductor device 100 includes a preparation step S1, an element isolation film formation step S2, a first ion implantation step S3, a gate insulating film formation step S4, a gate electrode formation step S5, a second ion implantation step S6, a sidewall spacer formation step S7, a third ion implantation step S8, a first interlayer insulating film formation step S9, a contact plug formation step S10, a first interconnect formation step S11, a second interlayer insulating film formation step S12, a via plug formation step S13, a second interconnect formation step S14, a protective film formation step S15, and a singulation step S16.

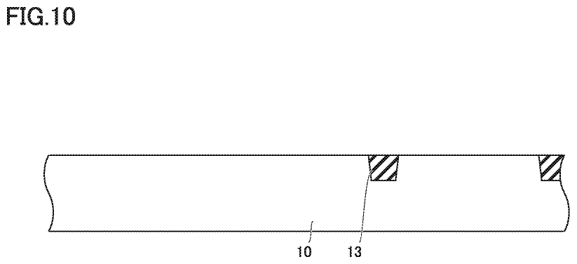

In preparation step S1, semiconductor substrate 10 is prepared. FIG. 10 is a cross-sectional view illustrating element isolation film formation step S2. As shown in FIG. 10, in element isolation film formation step S2, element isolation film 13 is formed. In element isolation film formation step S2, first, a hard mask is formed on main surface 10a. The hard mask is formed by stacking a silicon oxide film and a silicon nitride film by, for example, CVD (Chemical Vapor Deposition). Second, a resist pattern is formed on the hard mask. The resist pattern is formed by applying a photoresist and exposing and developing the applied photoresist. Third, the hard mask and semiconductor substrate 10 are etched using the resist pattern as a mask, to form a trench in main surface 10a.

Fourth, element isolation film 13 is embedded in the trench by, for example, CVD. Fifth, a portion of element isolation film 13 protruding from the trench is removed by CMP (Chemical Mechanical Polishing). Note that the hard mask is removed after element isolation film 13 is embedded in the trench.

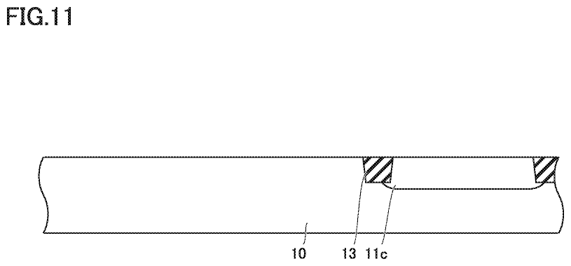

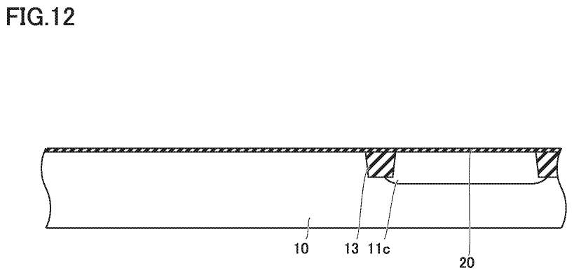

FIG. 11 is a cross-sectional view illustrating first ion implantation step S3. As shown in FIG. 11, in the first ion implantation step, ion implantation is performed to form well region 11c. FIG. 12 is a cross-sectional view illustrating gate insulating film formation step S4. As shown in FIG. 12, in gate insulating film formation step S4, main surface 10a is thermally oxidized, for example, to form gate insulating film 20 on main surface 10a.

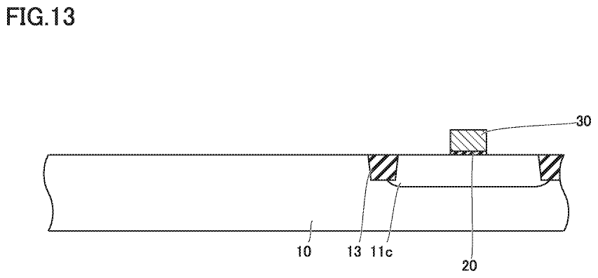

FIG. 13 is a cross-sectional view illustrating gate electrode formation step S5. As shown in FIG. 13, in gate electrode formation step S5, gate electrode 30 is formed. In gate electrode formation step S5, first, gate electrode 30 is formed on gate insulating film 20 by, for example, CVD. Second, a resist pattern is formed on gate electrode 30. The resist pattern is formed by applying a photoresist and exposing and developing the photoresist. Third, gate electrode 30 is patterned by etching using the resist pattern as a mask.

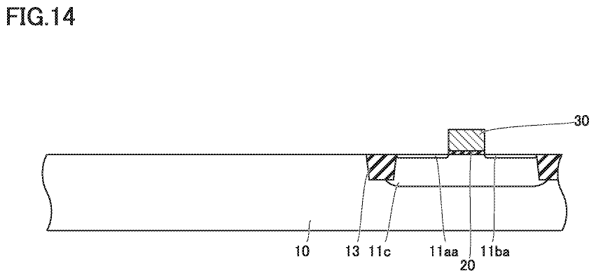

FIG. 14 is a cross-sectional view illustrating second ion implantation step S6. As shown in FIG. 14, in second ion implantation step S6, ion implantation is performed to form first region 11aa and first region 11ba.

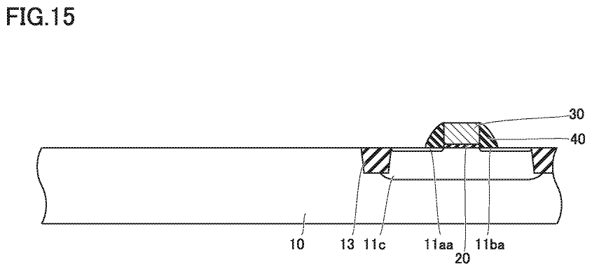

FIG. 15 is a cross-sectional view illustrating sidewall spacer formation step S7. As shown in FIG. 15, in sidewall spacer formation step S7, sidewall spacer 40 is formed. In sidewall spacer formation step S7, first, sidewall spacer 40 is formed on main surface 10a by, for example, CVD, so as to cover element isolation film 13, gate insulating film 20, and gate electrode 30. Second, an etch back is performed, for example, to remove sidewall spacer 40 except at positions adjacent to gate electrode 30.

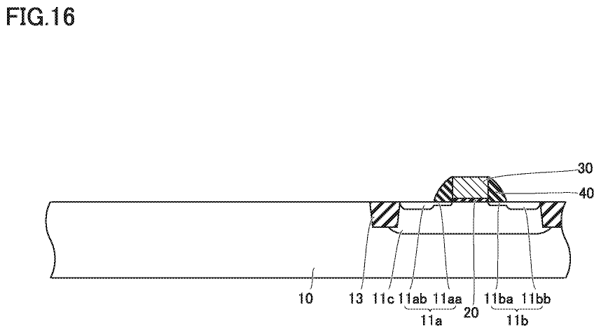

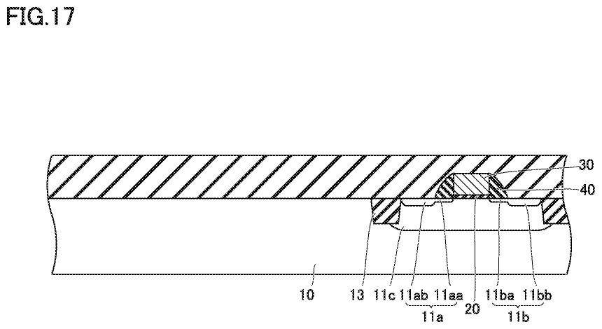

FIG. 16 is a cross-sectional view illustrating third ion implantation step S8. As shown in FIG. 16, in third ion implantation step S8, ion implantation is performed to form second region 11ab and second region 11bb. FIG. 17 is a cross-sectional view illustrating first interlayer insulating film formation step S9. As shown in FIG. 17, in first interlayer insulating film formation step S9, lowermost interlayer insulating film 50 is formed. In first interlayer insulating film formation step S9, first, interlayer insulating film 50 is formed on main surface 10a so as to cover element isolation film 13, gate electrode 30, and sidewall spacer 40. Second, an upper surface of interlayer insulating film 50 is planarized by, for example, CMP.

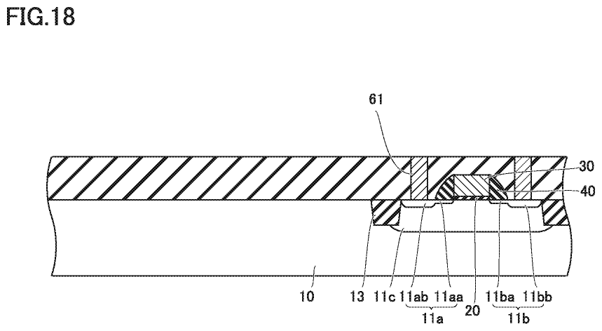

FIG. 18 is a cross-sectional view illustrating contact plug formation step S10. As shown in FIG. 18, in contact plug formation step S10, contact plug 61 is formed. In contact plug formation step S10, first, a resist pattern is formed on lowermost interlayer insulating film 50. The resist pattern is formed by applying a photoresist and exposing and developing the photoresist. Second, lowermost interlayer insulating film 50 is etched using the resist pattern as a mask, to form a contact hole.

Third, a metal film is formed on second region 11ab, second region 11bb and an upper surface of gate electrode 30 that are exposed at the contact hole, as well as on an inner wall surface of the contact hole and on lowermost interlayer insulating film 50, and heat treatment is subsequently performed. Thus, the metal film reacts with second region 11ab, second region 11bb and gate electrode 30, and silicidation is performed. After the silicidation is performed, the unreacted metal film is removed. Fourth, contact plug 61 is embedded in the contact hole by, for example, CVD. Fifth, a portion of contact plug 61 protruding from the contact hole is removed by, for example, CMP.

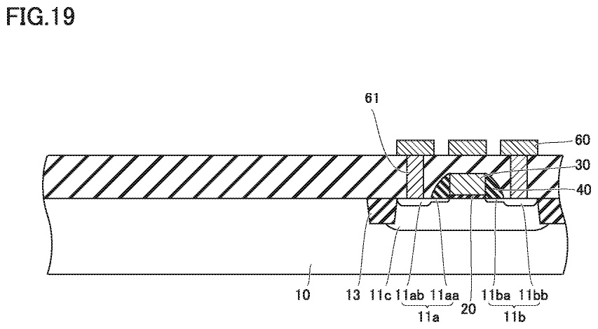

FIG. 19 is a cross-sectional view illustrating first interconnect formation step S11. As shown in FIG. 19, in first interconnect formation step S11, lowermost interconnect 60 is formed. In first interconnect formation step S11, first, lowermost interconnect 60 is formed on lowermost interlayer insulating film 50 by, for example, sputtering. Second, a resist pattern is formed on lowermost interconnect 60. The resist pattern is formed by applying a photoresist and exposing and developing the photoresist. Third, lowermost interconnect 60 is etched using the resist pattern as a mask, to pattern lowermost interconnect 60.

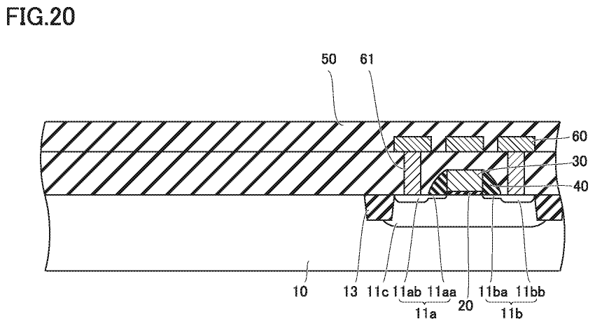

FIG. 20 is a cross-sectional view illustrating second interlayer insulating film formation step S12. As shown in FIG. 20, in second interlayer insulating film formation step S12, on one interlayer insulating film 50, another interlayer insulating film 50 is formed so as to cover interconnect 60 disposed on this one interlayer insulating film 50, by a method similar to that of first interlayer insulating film formation step S9.

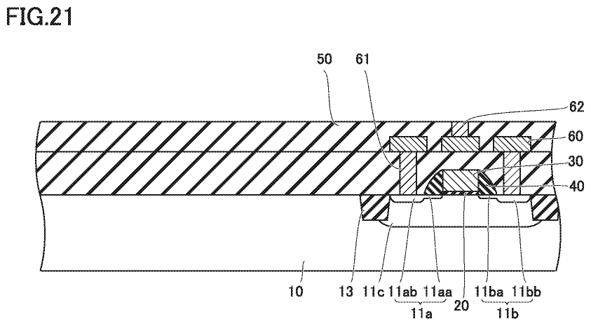

FIG. 21 is a cross-sectional view illustrating via plug formation step S13. As shown in FIG. 21, in via plug formation step S13, via plug 62 is formed. In via plug formation step S13, first, a resist pattern is formed on interlayer insulating film 50 other than the lowermost one. The resist pattern is formed by applying a photoresist and exposing and developing the photoresist. Second, interlayer insulating film 50 other than the lowermost one is etched using the resist pattern as a mask, to form a via hole. Third, via plug 62 is embedded in the via hole by, for example, CVD. Fourth, a portion of via plug 62 protruding from the via hole is removed by, for example, CMP.

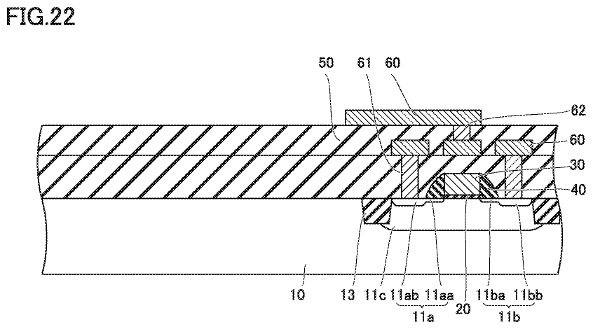

FIG. 22 is a cross-sectional view illustrating second interconnect formation step S14. As shown in FIG. 22, in second interconnect formation step S14, interconnect 60 other than the lowermost one is formed on one interlayer insulating film 50 by a method similar to that of first interconnect formation step S11. Second interlayer insulating film formation step S12, via plug formation step S13, and second interconnect formation step S14 are repeated until uppermost interconnect 60 is formed.

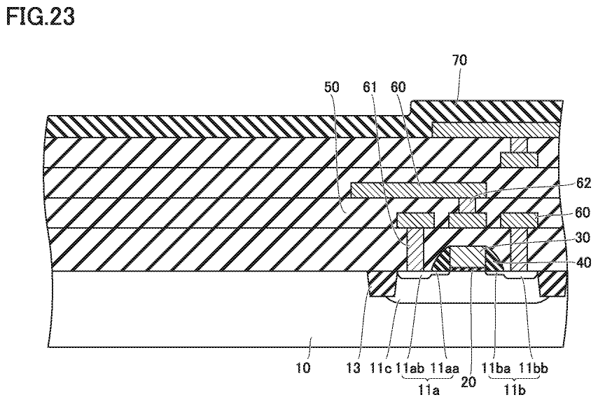

FIG. 23 is a cross-sectional view illustrating protective film formation step S15. As shown in FIG. 23, in protective film formation step S15, protective film 70 is formed. In protective film formation step S15, first, protective film 70 is formed on uppermost interlayer insulating film 50 by, for example, CVD, so as to cover uppermost interconnect 60. Second, a resist pattern is formed on protective film 70. The resist pattern is formed by applying a photoresist and exposing and developing the photoresist. Third, protective film 70 is etched using the resist pattern as a mask, to form an opening (not shown) in protective film 70 that exposes a pad of uppermost interconnect 60.

In singulation step S16, the semiconductor wafer thus formed is cut along a boundary region (scribe lane) between adjacent semiconductor devices 100, to be singulated into a plurality of semiconductor devices 100.

As shown in FIG. 9, the method of manufacturing semiconductor device 100 further includes a marking step S17. Marking step S17 is performed, for example, after preparation step S1 is performed and before element isolation film formation step S2 is performed. Marking step S17 may be performed between each step of the method of manufacturing semiconductor device 100.

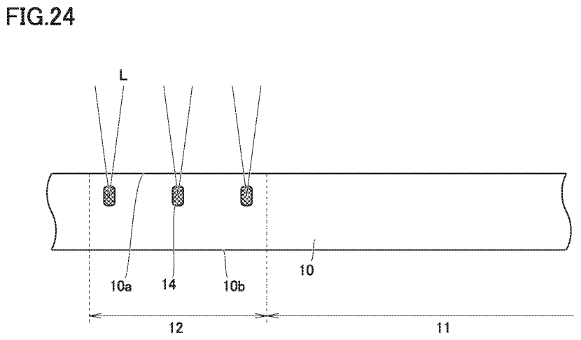

FIG. 24 is a cross-sectional view showing a first example of marking step S17. As shown in FIG. 24, in marking step S17, a laser beam L is applied so as to be focused and absorbed inside semiconductor substrate 10. Accordingly, a defect is partially introduced into a portion of semiconductor substrate 10 in the vicinity of a focused spot of laser beam L, thereby forming modified portion 14.

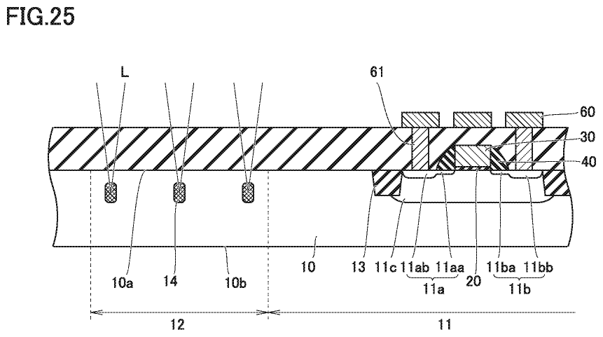

FIG. 25 is a cross-sectional view showing a second example of marking step S17. FIG. 25 shows an example in which marking step S17 is performed between each step of the method of manufacturing semiconductor device 100. As shown in FIG. 25, in this example as well, laser beam L is applied so as to be focused and absorbed inside semiconductor substrate 10, thereby forming modified portion 14 inside semiconductor substrate 10. In this example, however, laser beam L is focused and absorbed inside semiconductor substrate 10 by passing through interlayer insulating film 50 (and protective film 70) without passing through interconnect 60.

The position where modified portion 14 is formed in marking step S17 is determined based on MAP data. The MAP data includes, in addition to the lot number of the semiconductor wafer and the position of semiconductor device 100 on the semiconductor wafer, the result of the inspection conducted on semiconductor device 100 during the manufacturing steps and the like. Further, a wavelength of laser beam L having a low absorption rate for semiconductor substrate 10 and interlayer insulating film 50 is selected, and a focal position of laser beam L is adjusted, in order for laser beam L to be focused and absorbed inside semiconductor substrate 10.

### Effects of Semiconductor Device 100

The effects of semiconductor device 100 will be described below.

In the case where marking on semiconductor substrate 10 is performed by irradiating main surface 10a with a laser beam, the surface roughness of main surface 10a deteriorates in the vicinity of a portion irradiated with laser beam L. This may result in generation of particles that adversely affect the manufacturing steps, such as causing uneven application of a photoresist in a subsequent step.

In semiconductor device 100, on the other hand, marking on semiconductor substrate 10 is performed by forming modified portion 14 inside semiconductor substrate 10. In semiconductor device 100, therefore, the surface roughness of main surface 10a is less likely to deteriorate with the marking (more specifically, the arithmetic mean roughness of the portion of main surface 10a overlapping modified portion 14 in plan view can be 1 nm or less), so that the generation of particles that adversely affect the manufacturing steps is suppressed.

Further, in the case where marking on semiconductor substrate 10 is performed by irradiating main surface 10a with a laser beam, the marking on semiconductor substrate 10 can only be performed at the time of loading of semiconductor substrate 10. In semiconductor device 100, on the other hand, since the marking is performed by forming modified portion 14 inside semiconductor substrate 10, the marking can be performed not only at the time of loading of semiconductor substrate 10 but also during the manufacturing steps. As a result, in semiconductor device 100, information such as a result of an inspection conducted during the manufacturing of the semiconductor device can also be marked on semiconductor substrate 10.

The marking of the result of the inspection during the manufacturing of semiconductor device 100, the lot number of the semiconductor wafer from which semiconductor device 100 is obtained, the position of semiconductor device 100 on the semiconductor wafer and the like ensures traceability of semiconductor device 100. Even when semiconductor device 100 is in a packaged state (a state of being incorporated in semiconductor package 200), the marking (the manner of formation of modified portion 14) provided on semiconductor substrate 10 can be read by application of, for example, X-rays, infrared light, terahertz waves, visible light, or other electromagnetic waves. Therefore, semiconductor package 200 can ensure traceability without removing sealing member 220.

### Second Embodiment

A semiconductor device according to a second embodiment will be described. The semiconductor device according to the second embodiment will be referred to as a semiconductor device 100A. Here, differences from semiconductor device 100 will be mainly described, and redundant description will not be repeated.

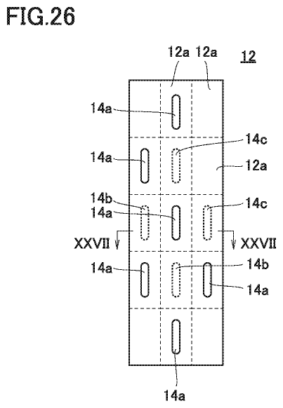

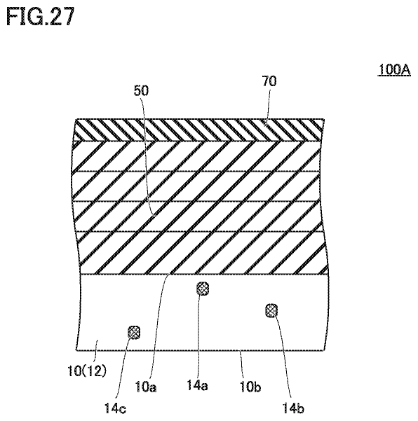

FIG. 26 is an enlarged plan view showing a first example of a manner of formation of modified portion 14 in semiconductor device 100A. FIG. 27 is a schematic cross-sectional view along XXVII-XXVII in FIG. 26. As shown in FIGS. 26 and 27, in semiconductor device 100A, a plurality of modified portions 14 may be arranged three-dimensionally. More specifically, the plurality of modified portions 14 include a plurality of modified portions 14a, a plurality of modified portions 14b, and a plurality of modified portions 14c.

The plurality of modified portions 14a are formed in a first plane, the plurality of modified portions 14b are formed in a second plane, and the plurality of modified portions 14c are formed in a third plane. The first plane, the second plane, and the third plane are, for example, planes parallel to main surface 10a. The first plane is located closer to main surface 10a than the second plane and the third plane. The second plane is located closer to main surface 10a than the third plane.

Each of the plurality of modified portions 14a is disposed so as not to overlap any of the plurality of modified portions 14b and the plurality of modified portions 14c in plan view. Each of the plurality of modified portions 14b is disposed so as not to overlap any of the plurality of modified portions 14a and the plurality of modified portions 14c in plan view. Each of the plurality of modified portions 14c is disposed so as not to overlap any of the plurality of modified portions 14a and the plurality of modified portions 14b in plan view.

In semiconductor device 100A, when reading a marking provided on semiconductor substrate 10, each of modified portion 14a, modified portion 14b and modified portion 14c can be read while being distinguished from one another by changing the depth of an observation focal point. For example, when the observation focal point is set to a shallow first position, modified portion 14a can be read, but modified portion 14b and modified portion 14c cannot be read. When the observation focal point is set to a third position deeper than the first position, modified portion 14c can be read, but modified portion 14a and modified portion 14b cannot be read. When the observation focal point is set to a second position intermediate between the first position and the third position, modified portion 14b can be read, but modified portion 14a and modified portion 14c cannot be read. In this way, by changing the observation focal point when reading the marking, modified portion 14 formed in a certain plane can be read while being distinguished from modified portion 14 formed in another plane.

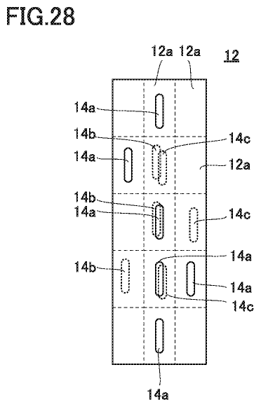

FIG. 28 is an enlarged plan view showing a second example of the manner of formation of modified portion 14 in semiconductor device 100A. As shown in FIG. 28, modified portion 14a may partially overlap modified portion 14b and may partially overlap modified portion 14c in plan view. Modified portion 14b may partially overlap modified portion 14c in plan view. In this case, when reading a marking, modified portion 14 formed in a certain plane can be read while being distinguished from modified portion 14 formed in another plane, by detecting a position displacement between modified portion 14a and modified portion 14b (a position displacement between modified portion 14a and modified portion 14c, a position displacement between modified portion 14b and modified portion 14c).

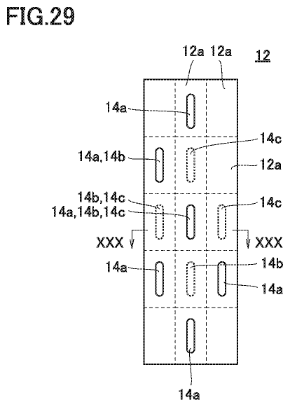

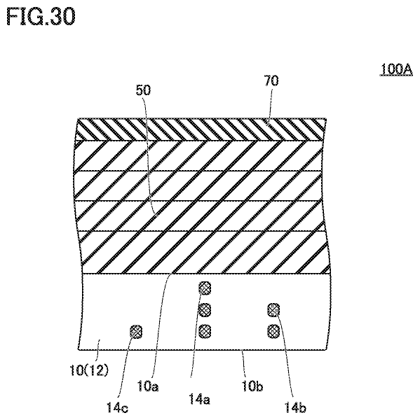

FIG. 29 is an enlarged plan view showing a third example of the manner of formation of modified portion 14 in semiconductor device 100A. FIG. 30 is a schematic cross-sectional view along XXX-XXX in FIG. 29. As shown in FIGS. 29 and 30, modified portion 14a may overlap modified portion 14b and may overlap modified portion 14c in plan view. Modified portion 14b may overlap modified portion 14c in plan view. In this case, three-dimensional arrangement information of modified portions 14 is acquired by synthesizing images obtained by irradiating semiconductor device 100A with X-rays or other electromagnetic waves while rotating semiconductor device 100A. Information regarding manufacturing steps of semiconductor device 100A can be read based on such three-dimensional arrangement information of modified portions 14.

### Third Embodiment

A semiconductor package according to a third embodiment will be described. The semiconductor package according to the third embodiment will be referred to as a semiconductor package 200A.

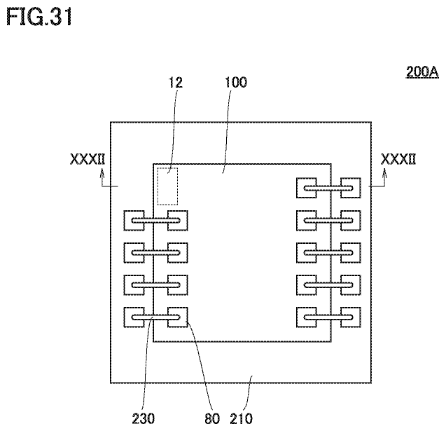

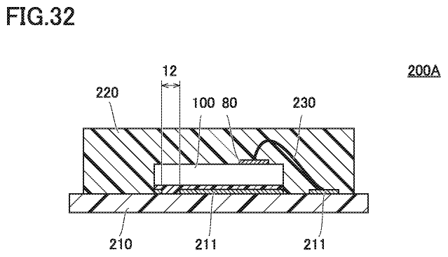

FIG. 31 is a plan view showing a first example of semiconductor package 200A. FIG. 32 is a schematic cross-sectional view along XXXII-XXXII in FIG. 31. As shown in FIGS. 31 and 32, in semiconductor package 200A, semiconductor device 100 is mounted on substrate 210. In semiconductor package 200A, a bonding pad 80 formed on an upper surface of semiconductor device 100 is connected to a conductor pattern 211 formed on an upper surface of substrate 210 by a bonding wire 230.

Bonding pad 80 is disposed so as not to overlap marking region 12 in plan view. Bonding wire 230 is disposed so as not to cross marking region 12 in plan view. Conductor pattern 211 is formed so as not to overlap marking region 12 in plan view. In this way, in semiconductor package 200A, a structure formed above or below semiconductor substrate 10 from a material that obstructs electromagnetic waves used for reading the marking provided on marking region 12, e.g., a metal material, does not overlap marking region 12 in plan view. According to semiconductor package 200A, therefore, the information regarding the manufacturing steps of semiconductor device 100 can be more reliably read.

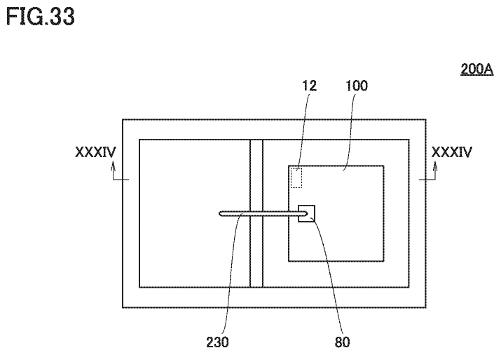

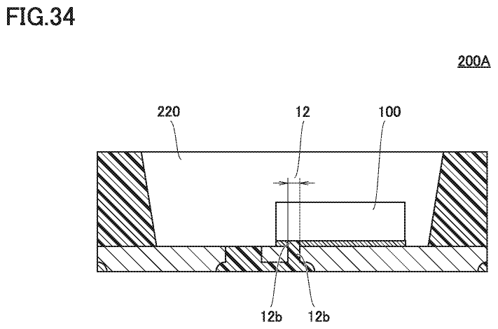

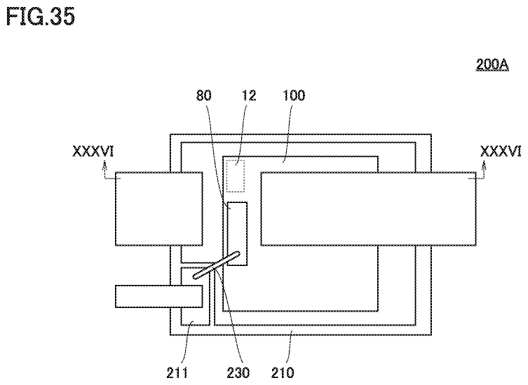

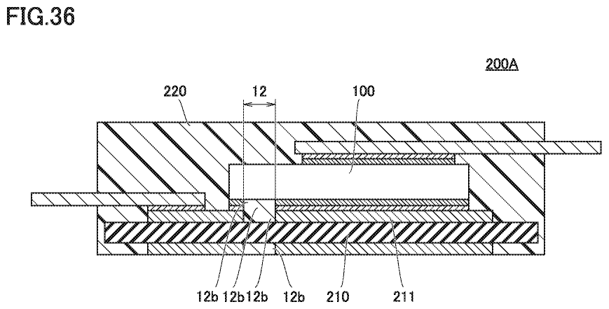

FIG. 33 is a plan view showing a second example of semiconductor package 200A. FIG. 34 is a schematic cross-sectional view along XXXIV-XXXIV in FIG. 33. FIG. 35 is a plan view showing a third example of semiconductor package 200A. FIG. 36 is a schematic cross-sectional view along XXXVI-XXXVI in FIG. 35. As shown in FIGS. 33 to 36, in semiconductor package 200A, semiconductor device 100 may not be an LSI (Large Scale Integrated circuit). As shown in FIGS. 33 and 34, semiconductor device 100 may be a discrete semiconductor such as an LED (Light Emitting Diode), and as shown in FIGS. 35 and 36, semiconductor device 100 may be a power semiconductor element such as a power MOSFET (Metal Oxide Semiconductor Field Effect Transistor) or an IGBT (Insulated Gate Bipolar Transistor). The power semiconductor element is not limited to a switching element, and may be a rectifying element such as an SBD (Schottky Barrier Diode) or an FRD (Fast Recovery Diode). Even in these cases, a structure formed above or below semiconductor substrate 10 from a material that obstructs electromagnetic waves used for reading the marking provided on marking region 12 (mainly, a wiring material such as a lead frame, a clip, or a bonding wire formed of a metal material such as aluminum or copper; or a bonding material such as solder used for bonding a semiconductor element and the wiring material) does not overlap marking region 12 in plan view. For example, a vertical power semiconductor element generally has a substrate with a high impurity concentration and an epitaxial layer with a low impurity concentration formed on the substrate by epitaxial growth, with an element structure such as a MOSFET or an SBD formed in the epitaxial layer. In this case, modified portion 14 constituting the marking may be formed in the epitaxial layer with a low impurity concentration or in the substrate with a high impurity concentration.

Note that the wiring material or the bonding material as mentioned above need only be configured so as not to overlap marking region 12 at least one of above and below semiconductor substrate 10. For example, in the case where electromagnetic waves used for reading the marking are applied from above, it is only required that no wiring material or bonding material be present above marking region 12, and the wiring material or the bonding material may overlap marking region 12 below marking region 12. Although FIGS. 33 to 36 show an example in which the wiring material or the bonding material does not overlap marking region 12 both above and below marking region 12, that is, the wiring material or the bonding material is provided with a gap portion 12b, the lower wiring material or bonding material may not be provided with gap portion 12b. Note that the wiring material mentioned here includes: an electrode material provided on a back surface of a semiconductor element; a lead frame on which a semiconductor element is mounted (see FIG. 34); and a substrate on which a semiconductor element is mounted (one having conductive wiring formed on both sides of an insulating substrate as in FIG. 36). In this case, the wiring material or the bonding material overlaps marking region 12 below marking region 12. Thus, the marking may be read using reflected light instead of transmitted light. The presence or absence of the wiring material or the bonding material overlapping marking region 12 is appropriately selected depending on the wavelength of an electromagnetic wave used for the reading; the material of the semiconductor element (silicon, silicon carbide, gallium nitride, or other materials); and the material, thickness and shape of the wiring material or the bonding material.

### Fourth Embodiment

A semiconductor device according to a fourth embodiment will be described. The semiconductor device according to the fourth embodiment will be referred to as a semiconductor device 100B.

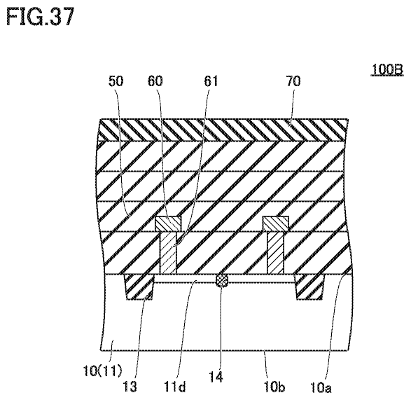

FIG. 37 is a cross-sectional view of semiconductor device 100B. As shown in FIG. 37, semiconductor substrate 10 has an impurity diffusion region 11d. Impurity diffusion region 11d is formed, for example, in main surface 10a located in device region 11. Both end portions of impurity diffusion region 11d form a diffusion resistor. Impurity diffusion region 11d is surrounded by element isolation film 13 in plan view. Impurity diffusion region 11d is electrically connected to interconnect 60 by contact plug 61. However, interconnect 60 is disposed so as not to overlap impurity diffusion region 11d in plan view, except at both end portions of impurity diffusion region 11d.

In semiconductor device 100B, modified portion 14 does not indicate information regarding manufacturing steps of semiconductor device 100B, and is not formed in marking region 12. In semiconductor device 100B, modified portion 14 is formed so as to partially overlap impurity diffusion region 11d. Note that impurity diffusion region 11d is formed by ion implantation in first ion implantation step S3, second ion implantation step S6, or third ion implantation step S8. Modified portion 14 is formed, for example, by focusing and absorbing laser beam L into impurity diffusion region 11d through protective film 70 and interlayer insulating film 50 after the structure of semiconductor device 100B other than modified portion 14 is formed.

Prior to the formation of modified portion 14, an electrical resistance value of the diffusion resistor (impurity diffusion region 11d) is measured. When the electrical resistance value of the diffusion resistor deviates from a desired value, modified portion 14 is formed to adjust the electrical resistance value of the diffusion resistor. After the formation of modified portion 14, the electrical resistance value of the diffusion resistor is measured again, and if it is within a desired range, the formation of modified portion 14 is completed. If the electrical resistance value of the diffusion resistor is measured and it is not within the desired range, on the other hand, the formation of modified portion 14 is continued. In this way, according to semiconductor device 100B, trimming of the diffusion resistor can be achieved by forming modified portion 14 while measuring the electrical resistance value of the diffusion resistor. In semiconductor device 100B, adjustment/trimming of source region 11a and drain region 11b may be achieved by forming modified portion 14. Although an impurity diffusion region in semiconductor substrate 10 is cited as an object to be trimmed in the present embodiment, the object to be trimmed is not limited as such. For example, polysilicon may be employed as the object to be trimmed and an electrical resistance value of the polysilicon may be adjusted, or a metal material may be employed as the object to be trimmed and an electrical resistance value of the metal material may be adjusted.

### ADDITIONAL ASPECTS

The embodiments of the present disclosure include the following aspects.

### Additional Aspect 1

A semiconductor device comprising:
a semiconductor substrate, wherein
a modified portion is formed inside the semiconductor substrate, and
the modified portion indicates information regarding manufacturing steps of the semiconductor device.

### Additional Aspect 2

The semiconductor device according to Additional Aspect 1, wherein
the semiconductor substrate has a marking region in plan view,
the marking region has a plurality of regions disposed in a matrix in plan view, and
the information is indicated by whether or not the modified portion is formed in each of the plurality of regions.

### Additional Aspect 3

The semiconductor device according to Additional Aspect 1, wherein
the modified portion extends along a first direction in plan view, and
the information is indicated by a spacing between two of the modified portions arranged along a second direction orthogonal to the first direction in plan view.

### Additional Aspect 4

The semiconductor device according to Additional Aspect 1, wherein
the modified portion includes a first modified portion, a second modified portion, and a third modified portion, and
the first modified portion, the second modified portion, and the third modified portion are formed at different positions in a thickness direction of the semiconductor substrate, and are disposed so as not to overlap one another in plan view.

### Additional Aspect 5

The semiconductor device according to Additional Aspect 1, wherein
the modified portion includes a first modified portion, a second modified portion, and a third modified portion, and
the first modified portion, the second modified portion, and the third modified portion are formed at different positions in a thickness direction of the semiconductor substrate, and are disposed so as to partially overlap one another in plan view.

### Additional Aspect 6

The semiconductor device according to Additional Aspect 1, wherein
the modified portion includes a first modified portion, a second modified portion, and a third modified portion, and
the first modified portion, the second modified portion, and the third modified portion are formed at different positions in a thickness direction of the semiconductor substrate, and are disposed so as to overlap one another in plan view.

### Additional Aspect 7

The semiconductor device according to Additional Aspect 1, wherein
the modified portion is formed so as to indicate a character or a number corresponding to the information in plan view.

### Additional Aspect 8

The semiconductor device according to any one of Additional Aspects 1 to 7, further comprising an interconnect disposed on the semiconductor substrate so as not to overlap the modified portion in plan view.

### Additional Aspect 9

The semiconductor device according to any one of Additional Aspects 1 to 8, wherein
the semiconductor substrate has a main surface, and
a portion of the main surface overlapping the modified portion in plan view has an arithmetic mean roughness of 1 nm or less.

### Additional Aspect 10

The semiconductor device according to any one of Additional Aspects 1 to 9, wherein
the information indicates at least one of: a result of an inspection during manufacturing of the semiconductor device; a lot number of a wafer from which the semiconductor device is obtained; a position of the semiconductor device on the wafer; a code of a company manufacturing the semiconductor device; a code of the semiconductor device; and an ID indicating a manufacturing apparatus used in the manufacturing steps.

### Additional Aspect 11

The semiconductor device according to Additional Aspect 1, wherein
the information varies for each of the semiconductor devices.

### Additional Aspect 12

A semiconductor package comprising:
the semiconductor device according to any one of Additional Aspects 1 to 11; and
a sealing member that seals the semiconductor device.

### Additional Aspect 13

The semiconductor package according to Additional Aspect 12, wherein
a portion at a position overlapping the modified portion in plan view is formed of a material that does not obstruct at least one of X-rays, infrared light, visible light, and terahertz waves.

### Additional Aspect 14

A method of manufacturing a semiconductor device, comprising:
preparing a semiconductor substrate; and
forming a modified portion inside the semiconductor substrate by focusing and absorbing a laser beam inside the semiconductor substrate, wherein
the modified portion indicates information regarding manufacturing steps of the semiconductor device.

### Additional Aspect 15

The method of manufacturing a semiconductor device according to Additional Aspect 14, further comprising:
forming an insulating film on the semiconductor substrate; and
forming an interconnect on the insulating film, wherein
the laser beam is focused and absorbed inside the semiconductor substrate by passing through the insulating film without passing through the interconnect.

### Additional Aspect 16

A semiconductor device comprising:
a semiconductor substrate, wherein
the semiconductor substrate has a main surface, an impurity diffusion region formed in the main surface, and a modified portion formed so as to partially overlap the impurity diffusion region.

Although the embodiments of the present disclosure have been described as above, the embodiments described above can also be modified in various manners. Further, the scope of the present invention is not limited to the embodiments described above. The scope of the present invention is defined by the terms of the claims, and is intended to include any modifications within the scope and meaning equivalent to the terms of the claims.

### REFERENCE SIGNS LIST

100 semiconductor device; 100A semiconductor device; 100B semiconductor device; 200 semiconductor package; 200A semiconductor package; 10 semiconductor substrate; 10a main surface; 10b main surface; 11 device region; 11a source region; 11aa first region; 11ab second region; 11b drain region; 11ba first region; 11bb second region; 11c well region; 11d impurity diffusion region; 12 marking region; 12a region; 12b gap portion; 13 element isolation film; 14 modified portion; 14a, 14b, 14c modified portion; 20 gate insulating film; 30 gate electrode; 40 sidewall spacer; 50 interlayer insulating film; 60 interconnect; 61 contact plug; 62 via plug; 70 protective film; 210 substrate; 220 sealing member; L laser beam; S1 preparation step; S2 element isolation film formation step; S3 first ion implantation step; S4 gate insulating film formation step; S5 gate electrode formation step; S6 second ion implantation step; S7 sidewall spacer formation step; S8 third ion implantation step; S9 first interlayer insulating film formation step; S10 contact plug formation step; S11 first interconnect formation step; S12 second interlayer insulating film formation step; S13 via plug formation step; S14 second interconnect formation step; S15 protective film formation step; S16 singulation step; S17 marking step; DR1 first direction; DR2 second direction.

1. A semiconductor device comprising:
a semiconductor substrate, wherein
a modified portion is formed inside the semiconductor substrate, and
the modified portion indicates information regarding manufacturing steps of the semiconductor device.

2. The semiconductor device according to claim 1, wherein
the semiconductor substrate has a marking region in plan view,
the marking region has a plurality of regions disposed in a matrix in plan view, and
the information is indicated by whether or not the modified portion is formed in each of the plurality of regions.

3. The semiconductor device according to claim 1, wherein
the modified portion extends along a first direction in plan view, and
the information is indicated by a spacing between two of the modified portions arranged along a second direction orthogonal to the first direction in plan view.

4. The semiconductor device according to claim 1, wherein
the modified portion includes a first modified portion, a second modified portion, and a third modified portion, and
the first modified portion, the second modified portion, and the third modified portion are formed at different positions in a thickness direction of the semiconductor substrate, and are disposed so as not to overlap one another in plan view.

5. The semiconductor device according to claim 1, wherein
the modified portion includes a first modified portion, a second modified portion, and a third modified portion, and
the first modified portion, the second modified portion, and the third modified portion are formed at different positions in a thickness direction of the semiconductor substrate, and are disposed so as to partially overlap one another in plan view.

6. The semiconductor device according to claim 1, wherein
the modified portion includes a first modified portion, a second modified portion, and a third modified portion, and
the first modified portion, the second modified portion, and the third modified portion are formed at different positions in a thickness direction of the semiconductor substrate, and are disposed so as to overlap one another in plan view.

7. The semiconductor device according to claim 1, wherein
the modified portion is formed so as to indicate a character or a number corresponding to the information in plan view.

8. The semiconductor device according to claim 1, further comprising an interconnect disposed on the semiconductor substrate so as not to overlap the modified portion in plan view.

9. The semiconductor device according to claim 1, wherein
the semiconductor substrate has a main surface, and
a portion of the main surface overlapping the modified portion in plan view has an arithmetic mean roughness of 1 nm or less.

10. The semiconductor device according to claim 1, wherein
the information indicates at least one of: a result of an inspection during manufacturing of the semiconductor device; a lot number of a wafer from which the semiconductor device is obtained; a position of the semiconductor device on the wafer; a code of a company manufacturing the semiconductor device; a code of the semiconductor device; and an ID indicating a manufacturing apparatus used in the manufacturing steps.

11. The semiconductor device according to claim 1, wherein
the information varies for each of the semiconductor devices.

12. A semiconductor package comprising:
the semiconductor device according to claim 1; and
a sealing member that seals the semiconductor device.

13. The semiconductor package according to claim 12, wherein
a portion at a position overlapping the modified portion in plan view is formed of a material that does not obstruct at least one of X-rays, infrared light, visible light, and terahertz waves.

14. A method of manufacturing a semiconductor device, comprising:
preparing a semiconductor substrate; and
forming a modified portion inside the semiconductor substrate by focusing and absorbing a laser beam inside the semiconductor substrate, wherein
the modified portion indicates information regarding manufacturing steps of the semiconductor device.

15. The method of manufacturing a semiconductor device according to claim 14, further comprising:
forming an insulating film on the semiconductor substrate; and
forming an interconnect on the insulating film, wherein
the laser beam is focused and absorbed inside the semiconductor substrate by passing through the insulating film without passing through the interconnect.
